(19) United States
(12) Patent Application Publication
(10) Pub. No.: US 2026/0123309 A1
(43) Pub. Date: Apr. 30, 2026

(54) METHOD FOR PRODUCING A SEMICONDUCTOR DEVICE AND SEMICONDUCTOR DEVICE

(71) Applicant: Hitachi Energy Ltd, Zürich (CH)

(72) Inventors: Giovanni ALFIERI, Möriken (CH); Gianpaolo ROMANO, Baden (CH); Yulieth Cristina ARANGO, Zürich (CH)

(21) Appl. No.: 19/151,292

(22) PCT Filed: Feb. 13, 2023
(86) PCT No.: PCT/EP2023/053470

§ 371 Date: Jul. 25, 2025

(51) Int. Cl. H10P 32/10

(52) U.S. Cl. CPC H10P 32/172

(57) ABSTRACT

In at least one embodiment, the method is for producing a semiconductor device (1) and comprises the following steps in the stated order: A) providing a semiconductor body (2) having a top side (20), the semiconductor body (2) is based on SiC, B) producing a first layer (21) of the semiconductor body (2) next to the top side (20) by doping with a dopant (4), C) applying a carbon-containing layer (3) on the top side (20), D) implanting C into the first layer (21) through the carbon-containing layer (3), and E) performing a temperature treatment of the semiconductor body (2) when the carbon-containing layer (3) is still present on the top side (20).

A method for manufacturing a semiconductor device is provided. A corresponding semiconductor device is also provided.

Document L. Storasta et al., “Reduction of traps and improvement of carrier lifetime in 4H-SiC” in Appl. Phys. Lett. 90, 062116 (2007); https://doi.org/10.1063/1.2472530, refers to reduction in deep level defects.

Document H. M. Ayedh et al., “Elimination of carbon vacancies in 4H-SiC epi-layers by near-surface ion implantation: Influence of the ion species” in Journal of Applied Physics 118, 175701 (2015); https://doi.org/10.1063/1.4934947, refers to methods for addressing carbon vacancies.

Document K. Hamada et al., patent application publication US 2016/0247894 A1, refers to a method for manufacturing a semiconductor device capable of reducing an ON resistance, wherein a drift layer is formed on a substrate, and an ion implanted layer is formed in a surface of the drift layer. A surplus carbon region is formed in the drift layer. The drift layer is heated.

Document B. Zippelius et al., “High temperature annealing of n-type 4H-SiC: Impact on intrinsic defects and carrier lifetime” in J. Appl. Phys. 111, 033515 (2012); http://dx.doi.org/10.1063/1.3681806, refers to carrier lifetime in SiC.

An object to be achieved is to provide a semiconductor device that has improved electrical behavior.

This object is achieved, inter alia, by a power semiconductor device and by a method as defined in the independent patent claims. Exemplary further developments constitute the subject-matter of the dependent claims.

In at least one embodiment, the method for producing a semiconductor device comprises the following steps which may be performed in the stated order:
A) providing a semiconductor body having a top side, the semiconductor body is based on SiC,
B) producing a first layer of the semiconductor body, for example, next to the top side by doping with a dopant,
C) applying a carbon-containing layer on the top side,
D) implanting C into the first layer through the carbon-containing layer, and
E) performing a temperature treatment of the semiconductor body when the carbon-containing layer is still present on the top side.

With this method, carbon vacancy removal by low-dose C implant using a carbon-containing layer, also referred to as C-cap, can efficiently be achieved. Hence, removal of carbon vacancies during device processing is enabled.

The carbon vacancy, V_{c}, is one of the most important point defects in n-type 4H silicon carbide, 4H-SiC. V_{c} gives rise to two electrically active levels in the bandgap labelled Z_{1/2} and EH_{6/7}, located at 0.65 eV and 1.6 eV below the conduction band edge, E_{c}, respectively. In particular, Z_{1/2} is a recombination center, affecting the charge carriers' lifetime in bipolar devices and increasing the leakage current in unipolar devices.

A method for the reduction of V_{c} concentration, [V_{c}], was presented by Storasta et al., see citation above. This consists in performing a shallow 100 nm to 2000 nm deep box-profile C-ion implantation with implantation energies of 10 keV to 10 MeV into a SiC epilayer and subsequent annealing at high temperature of 1200° C. to 2200° C. In this way, C-interstitials, Cᵢ, formed by ion implantation diffuse into the epilayer and recombine with V_{c}, resulting in a reduction of [V_{c}]. Another method was proposed by Ayedh et al., see citation above, which is based on a low temperature, that is, less than 1500° C., annealing using a C-cap. Both methods are based on the diffusion of Cᵢ, that eventually recombine with V_{c} in a drift layer, according to Cᵢ+V_{c}→∅, thus increasing the minority carrier lifetime. The term ‘epilayer’ refers to an epitaxially grown layer. For example, the epilayer is grown onto a substrate which may be of a same base material, like SiC.

However, when a p⁺in diode is manufactured, by using an epilayer that has been processed according to one of the two methods described above, Al implantation for anode formation and subsequent annealing lead to the re-generation of V_{c}.

Hamada et al., see citation above, have suggested to perform deep C-implantation in the epilayer, within 500 nm from the Al box profile, using high doses of more than 10¹³ cm⁻². During activation, Cᵢ will diffuse in the epilayer from these deeply implanted regions. However, such high doses can lead to amorphization of the epilayer crystalline structure. Cᵢ are also acceptors in n-type 4H-SiC and a high concentration of Cᵢ can lead to n-type doping compensation. In the same way, if a high dose of C is implanted in the anode layer, that is, the first layer, formation of implantation-related defects occurs that can compensate pt doping. In the method described herein, the C implantation dose is low, so said p⁺ doping compensation is avoided or this effect is strongly reduced. The low C dose will also prevent the degradation of the hole injection efficiency from the anode, as this can decrease due to the presence of defects in the p⁺ region.

In the method described herein, implantation of C in the p⁺ implanted area, that is, an anode, is performed, followed by annealing using a C-cap. This has the advantage of, for example, using lower implantation doses and energies than those of Hamada et al., and removing V_{c} in a pin diode, unlike the case in Ayedh et al., as in the latter it is shown that by C-cap annealing, the concentration of V_{c} is reduced, but some is still present. In the method described herein, extra Cᵢ is supplied, by doing low-dose C implantation in the anode layer. So, Cᵢ coming from the C-cap plus Cᵢ coming from the C implanted is present in the anode layer. All of these Cᵢ together remove V_{c} completely or virtually completely from a drift layer, for example.

Hence, the method herein particularly includes the low dose implantation of C in, for example, an Al box profile, followed by annealing using a C-cap.

According to at least one embodiment, a concentration of the dopant provided in step B) and being activated is at least three times or is at least six times a concentration of C implanted in step D). Alternatively or additionally, the concentration of the finally activated dopant is at most 30 times or is at most 15 times the implanted C concentration. That is, the concentration of activated dopant in the finished semiconductor device is about ten times the implanted C concentration of step B).

It is noted that not all of the implanted dopant will be activated, that is, for example, available for conduction of charge carriers in the finished device. For example, in case of Al as the dopant, about 2% of the implanted Al are actually activated. That is, for example, an Al implanted concentration of 1×10²⁰ cm⁻³ results in a concentration of about 2×10¹⁸ cm⁻³ of activated Al.

According to at least one embodiment, in step E) the temperature treatment includes applying a first temperature. For example, the first temperature is at least 1400° C. or is at least 1500° C. Alternatively or additionally, the first temperature is at most 1800° C. or is at most 1700° C. or is at most 1650° C. With such a first temperature, in step E) previously implanted C can diffuse from the carbon-containing layer, that is, the C-cap, into the first layer and optionally also into a second layer of the semiconductor body, like an intrinsically doped layer.

According to at least one embodiment, the method further comprises a step B2). For example, step B2) is performed after step B) and previous to steps D). In step B2), the dopant is activating by applying a second temperature. For example, the second temperature is at least 1400° C. or is at least 1500° C. or is at least 1600° C. Alternatively or additionally, the first temperature is at most 1900° C. or is at most 1800° C. or is at most 1750° C. It is possible that the second temperature is between 50° C. and 150° C. higher than the first temperature.

For example, both temperature treatments at the first and at the second temperature are performed during the method.

According to at least one embodiment, in step E) C diffuses from the carbon-containing layer into the first layer and/or into the second layer, and the dopant is activated. For example, in step E) the temperature treatment includes applying a third temperature. For example, the third temperature is at least 1400° C. or is at least 1500° C. or is at least 1550° C. Alternatively or additionally, the third temperature is at most 1900° C. or is at most 1800° C. or is at most 1750° C. or is at most 1650° C. When the third temperature is applied, then there may be no temperature treatment with the first or second temperature.

According to at least one embodiment, between steps A) and E) a temperature of the semiconductor body (2) is kept below 800° C. or below 500° C. or below 300° C. or below 100° C. This applies, for example, when the temperature treatment at the third temperature is performed. In other words, in this case C diffusion and dopant activation can be done in the same temperature treatment step without the need for an intermediate temperature step.

According to at least one embodiment, the dopant is aluminum, Al. Otherwise, the dopant can be B or Ga or In. In case of an n-doped first layer, other dopants, like P, As, Sb and/or Bi, can be used as well. It is also possible that co-doping is used, that is, that at least two different dopants are used. Hence, in step B) at least one dopant is introduced into the first layer of the semiconductor body, either by means of implantation, thermal diffusion or epitaxial growth, or any combination thereof.

According to at least one embodiment, in step B) the doping is provided by means of ion implantation. For example, different ion implantation energies are used to achieve a box profile of the at least one dopant. The ion implantation energies are, for example, between 10 keV and 10 MeV inclusive and may be between 30 keV and 300 keV, for example.

According to at least one embodiment, the first layer is p-doped.

According to at least one embodiment, the at least one dopant is provided by means of ion implantation with a dose of at least 1×10¹³ cm⁻² or at least 1×10¹⁴ cm⁻² or at least 2×10¹⁴ cm⁻². Alternatively or additionally, said dose is at most 1×10¹⁶ cm⁻² or at most 1×10¹⁵ cm⁻² or at most 6×10¹⁴ cm⁻² or at most 4×10¹⁴ cm⁻².

According to at least one embodiment, C is implanted with a dose of at least 5×10⁸ cm⁻² or at least 1×10⁹ cm⁻² or at least 2×10⁹ cm⁻². Alternatively or additionally, said dose is at most 1×10¹² cm⁻² or at most 1×10¹¹ cm⁻² or at most 5×10¹⁰ cm⁻² or at most 1×10¹⁰ cm⁻².

According to at least one embodiment, the first layer is produced next to the top side by doping with the at least one dopant. Hence, the first layer can be directly at the top side so that the top side is formed partially or completely by the first layer. Alternatively, the first layer may at least partially be buried in the semiconductor body so that the top layer may partially or completely be distant from the top side.

According to at least one embodiment, the carbon-containing layer is applied directly on the top side, for example, directly on the first layer. Otherwise, there can be at least one intermediate layer between the carbon-containing layer and the top side and/or between the carbon-containing layer and the first layer.

For example, the carbon-containing layer is a continuous, hole-free layer. The carbon-containing layer may extent all over the semiconductor body. It is possible that the carbon-containing layer is used in method steps D) and E) as applied, that is, without material removal or structuring of the carbon-containing layer in the meantime. Hence, the carbon-containing layer may be used in steps D) and E) with a coverage of the semiconductor body as originally put onto the semiconductor body.

According to at least one embodiment, wherein in step D) a first implantation energy is at least 10 keV and/or is at most 300 keV.

According to at least one embodiment, the at least one dopant and/or C is applied with a box profile. The term ‘box profile’ may also be referred to as multiple energy implantation profile. That is, a concentration of the respective dopant and/or of C is approximately constant along a depth direction.

According to at least one embodiment, after step D) or after step E) a first box profile depth of the at least one dopant is larger than a second box profile depth of C. For example, the respective depth refers to a depth at which the concentration has fallen to 1/e of a maximum concentration of the respective dopant or C, wherein e≈2.7183 is Euler's number. For example, the second box profile depth is at least 30% or at least 45% and/or is at most 80% or is at most 60% of the first box profile depth.

According to at least one embodiment, the first box profile depth is at least 0.1 μm or is at least 0.2 μm or is at least 0.3 μm. Alternatively or additionally, the first box profile depth is at most 1.5 μm or is at most 1.2 μm or is at most 0.7 μm.

According to at least one embodiment, the method further comprises a step B1). For example, step B1 is performed after step B) and prior to step C). In step B1), the semiconductor body is etched. By this etching, for example, a mesa is formed. The mesa is an elevated part of the semiconductor body so that next to the mesa part of the semiconductor body is removed. It is possible that step B1) is done between steps B) and B2).

According to at least one embodiment, an etching depth in step B1) is larger than a thickness of the first layer, that is, the first box profile depth. For example, the etching depth exceeds the first box profile depth by at least a factor of 1.2 and/or by at most a factor of three.

According to at least one embodiment, in step C) the carbon-containing layer is applied all over the semiconductor body or only over portions of the semiconductor body. If the mesa is present, the carbon-containing layer may completely cover the top side of the mesa and side walls of the mesa.

According to at least one embodiment, the carbon-containing layer comprises or consist of at least one of graphite, a graphitic material, and diamond-like carbon, DLC for short. That is, the carbon-containing layer can consist or essentially consist of C.

According to at least one embodiment, the carbon-containing layer comprises or consists of a photoresist. For example, said photoresist has been developed and/or baked to become the carbon-containing layer. That is, the carbon-containing layer can comprise further elements in addition to C, like H and/or O and/or N.

According to at least one embodiment, a thickness of the carbon-containing layer is at least 0.1 μm or is at least 0.2 μm. Alternatively or additionally, said thickness is at most 1.5 μm or is at most 0.9 μm or is at most 0.6 μm.

According to at least one embodiment, in the finished semiconductor device the semiconductor body further comprises the second layer. For example, the second layer is directly on a side of the first layer remote from the top side. If there is a mesa, it is possible that the second layer is exposed in places and/or that the etching terminates in the second layer.

According to at least one embodiment, the second layer is doped with a lower doping concentration than the first layer or is not doped. Thus, the second layer could be an intrinsically doped layer. For example, a doping concentration of the second layer is at most 1×10¹⁵ cm⁻³ or at most 5×10¹⁴ cm⁻³ or at most 1×10¹⁴ cm⁻³ or at most 5×10¹³ cm⁻³.

According to at least one embodiment, a thickness of the second layer is at least 10 μm. Alternatively or additionally, said thickness is at most 100 μm or at most 50 μm.

According to at least one embodiment, the first layer or the overall semiconductor body is of 4H-SiC.

According to at least one embodiment, in the finished semiconductor device the first layer is an anode layer. For example, the first layer is in direct contact with a semiconductor contact layer, like a plug, and the semiconductor contact layer may be in direct contact with an electrode, like a metallic electrode or a poly-Si electrode. It is possible that the semiconductor contact layer is regarded as being part of the first layer because of the same conductivity type, like p-conductive, although the semiconductor contact layer may have a higher doping concentration that remaining parts of the first layer.

A semiconductor device is additionally provided. By means of the method as indicated in connection with at least one of the above-stated embodiments, the semiconductor device can be produced. Features of the semiconductor device are therefore also disclosed for the method and vice versa.

In at least one embodiment, the semiconductor device comprises a semiconductor body. The semiconductor body comprises a first layer of 4H-SiC directly at a top side of the semiconductor body. The first layer comprises a dopant with a concentration of the activated dopant of at least 2×10¹⁷ cm⁻³ and/or of at most 8×10¹⁸ cm⁻³. A concentration of carbon vacancies in the first layer next to the top side is at most 2×10¹¹ cm⁻³.

According to at least one embodiment, the semiconductor device is a pin diode or is an insulated-gate bipolar transistor, IGBT, or a reverse-conducting insulated-gate bipolar transistor, RC-IGBT, or a metal-insulator-semiconductor field-effect transistor, MISFET, or a metal-oxide-semiconductor field-effect transistor, MOSFET.

The semiconductor device is, for example, a power device or part of a power device to convert direct current from a battery to alternating current for an electric motor, for example, in vehicles like hybrid vehicles or plug-in electric vehicles or also in railways, like commuter trains.

For example, the semiconductor device is configured for a maximum voltage between its two electrodes, or between a source or emitter electrode and a drain or collector electrode, of at least 0.2 kV or of at least 0.6 kV or of at least 1.2 kV. Alternatively or additionally, the semiconductor device is configured for a current between its two electrodes, or between the source or emitter electrode and the drain or collector electrode, of at least 0.01 kA or of at least 0.1 kA of at least 1 kA and/or of at most 100 kA or of at most 10 kA.

A method and a semiconductor device described herein are explained in greater detail below by way of exemplary embodiments with reference to the drawings. Elements which are the same in the individual figures are indicated with the Same reference numerals. The relationships between the elements are not shown to scale, however, but rather individual elements may be shown exaggeratedly large to assist in understanding.

In the figures:

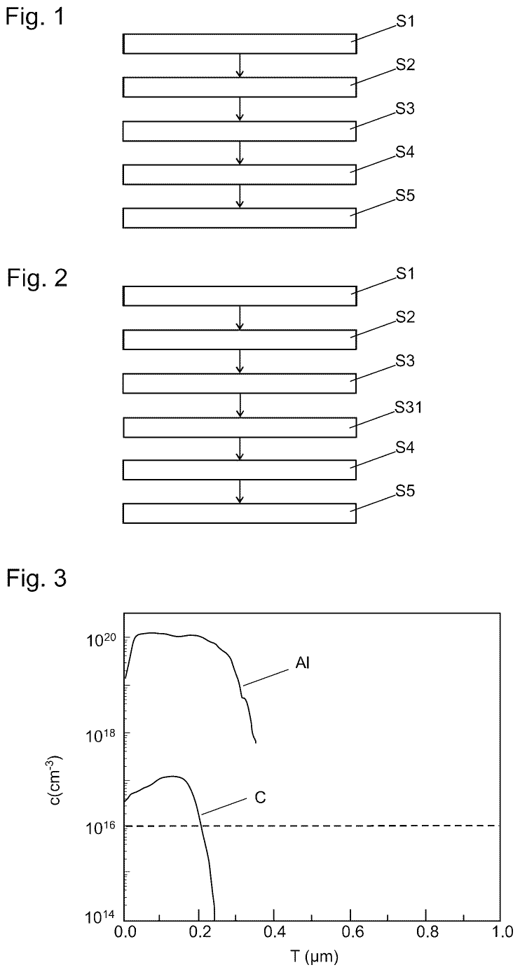

FIGS. 1 and 2 are schematic block diagrams of exemplary embodiments of methods for manufacturing semiconductor devices described herein,

FIG. 3 is a schematic representation of doping profiles provided by methods described herein,

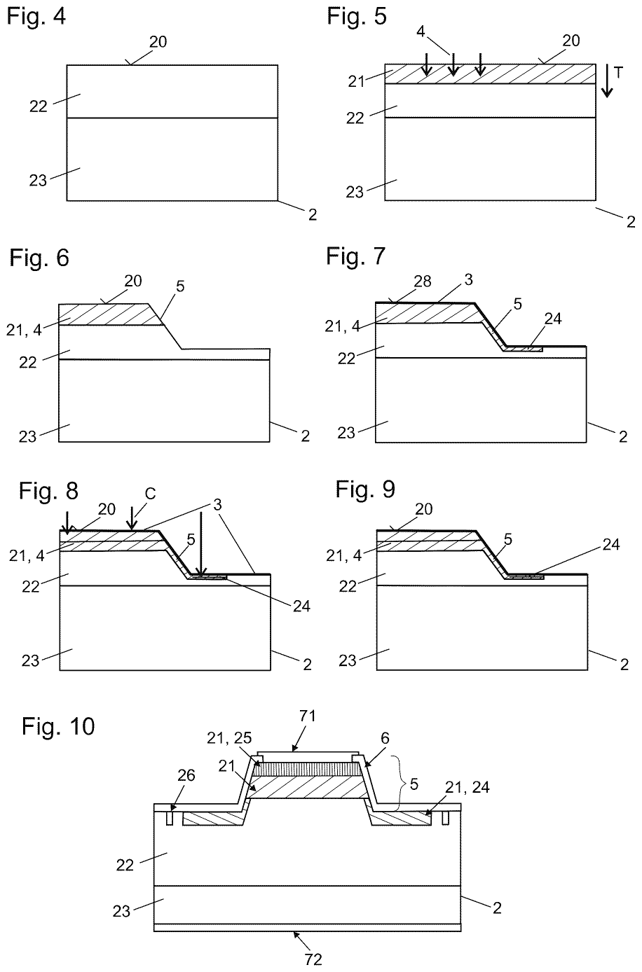

FIGS. 4 to 9 are schematic sectional views of method steps of an exemplary embodiment of a method for manufacturing semiconductor devices described herein,

FIGS. 10 to 12 are schematic sectional views of exemplary embodiments of semiconductor devices described herein, and

FIG. 13 is a representation of deep level transient spectroscopy data of an exemplary embodiment of a semiconductor device described herein and of a comparative example.

FIGS. 1 and 2 are schematic representations of methods to produce semiconductor devices 1. In a method step S1, a semiconductor body 2 is provided, see also the description on FIGS. 4 to 9 below. For example, the semiconductor body is of SiC.

Subsequently, in method step S2, a first layer 21 of the semiconductor body 2 is produced by doping a respective region of the semiconductor body 2 with a dopant 4. For example, the first layer 21 is p-doped in step S2. This can be achieved, for example, by ion implantation with the dopant 4. The dopant 4 is, for example, Al.

Then, in step S3, a carbon-containing layer 3 is applied on a top side 20 of the semiconductor body 2. The top side 20 can be formed partially or completely by the first layer 21.

In a subsequent step S4 C is implanted into the first layer with a lower concentration than the dopant 4.

According to FIG. 1, in step S5 a temperature treatment is performed at a third temperature. In this step, both the dopant is activated and C can diffuse from the carbon-containing layer 3 into the semiconductor body 2, for example, into and/or through the first layer 21. Hence, in the method of FIG. 1 in the relevant method steps there is only one temperature treatment of the semiconductor body 2 at an elevated temperature of, for example, above 1000° C.

Contrary to that, in FIG. 2 it is illustrated that there is step S31. In step S31, a temperature treatment at a second temperature is performed. During this temperature treatment, the dopant 4 is activated. Then, after step S4, there is also step S5, but in this step S5 diffusion of C occurs at a first temperature. Hence, in the method of FIG. 2 the activation and the diffusion can be performed separated from each other. It is possible that the first temperature is lower than the second temperature.

In FIG. 3, resulting doping profiles of the dopant 4, like Al, and of the implanted C are illustrated. Both profiles are box profiles. It is noted that in FIG. 3 the implanted concentration c of the dopant 4 and not a concentration of activated dopant 4 is shown. The concentration of the activated dopant 4 is about two order of magnitude lower than the actually implanted concentration c of the dopant 4. Thus, a maximum implanted concentration c of the dopant 4 is about three order of magnitude higher than a maximum implanted concentration c of C.

As can also be seen from FIG. 3, the box profile of the dopant 4 has a depth T of about 0.3 μm to 0.4 μm. A depth T of the box profile of the implanted C is about 0.2 μm. Next to the top side 20, the doping concentration c is in both cases relatively low, compared with the maximum implanted concentrations.

For example, the methods of FIGS. 1 and 2 may be performed as follows:

First, the anode, that is, the first layer 21, is formed by Al ion implantation. For instance, Al implantation energies of 30 keV, 60 keV, 110 keV and 180 keV and a total dose of 10¹⁵ cm⁻², performed at temperatures of at least 100° C., will lead to an Al concentration, [Al], plateau of about 10²⁰ cm⁻³ and to a box profile depth of about 0.4 μm. After this, Al activation is carried out at a temperature of 1700° C. for 30 min.

Then, C implantation is performed in the p⁺ area, that is, part of the first layer 21, through the previously applied C-cap, that is, the carbon-containing layer 3, which has a thickness of, for example, about 0.15 μm. C implantation energies should be chosen so that the C-implant profile is within 0.1 μm from the Al box profile tail region located at T≈0.4 μm. The implant C dose should be chosen so that the implanted Cᵢ concentration is lower than the implanted [Al], after activation. By assuming an activation ratio of 2% of the dopant 4, the implanted [Cᵢ] is, for example, at most 10¹⁷ cm⁻³, corresponding to [Al]/[Cᵢ]>10. For example, for the profile of FIG. 3, C has been implanted at 80 keV and with a dose of 5×10⁹ cm⁻².

At last, annealing at at most 1600° C. is carried out to diffuse the Cᵢ. Cᵢ, coming from the C-cap, will also be injected in a second layer of the semiconductor body 2, like a drift layer. Since their concentration is not sufficient to decrease [Z_{1/2}] to below a detection limit, which is, for example, around 10¹⁰ cm⁻³, the implanted Cᵢ will top them up.

Alternatively, see FIG. 2, C implantation can be performed before Al activation. In this case, the activation temperature also allow Cᵢ diffusion.

Longer annealing times of, for example, at least 30 min, can be chosen so to diffuse Cᵢ in thicker second layers 22 having a thickness of about 100 μm.

As a result, the [V_{c}] will decrease to below the detection limit. Two other levels may be detected, called ON1 and ON2, compare B. Zippelius et al. as cited above. These levels have no impact on device performance. It is noted that, for example, in a standard p⁺in diode, a certain amount of V_{c} is always detected, due to p⁺ activation.

For example, by means of deep-level transient spectroscopy, DLTS, the presence of V_{c} (Z_{1/2}) can be demonstrated in a p⁺n diode not treated as described herein, and also the absence of V_{c} in a p⁺n diode treated with the described method and appearance of ON1 and ON2 can be demonstrated.

In FIGS. 4 to 9, an example for producing a semiconductor device 1 which is a pin diode is illustrated. According to FIG. 4, the semiconductor body 2 is provided. The semiconductor body 2 includes a third layer 23 on a second layer 22. The second layer 22 is, for example, intrinsically doped or only very weakly n-doped. The third layer 23 is, for example, n-doped. The top side 20 is at the second layer 22. The third layer 23 and/or the second layer 22 may be provided by means of epitaxy.

In FIG. 5 it is shown that the first layer 21 is formed by doping the semiconductor body 2 next to the top side 20 with the dopant 4 which is, for example, Al. A thickness of the first layer 21 is, for example, about 0.4 μm.

After that, a mesa 5 is formed by etching, see FIG. 6. The etching terminates in the second layer 22 so that the first layer 21 is completely removed in places.

According to FIG. 7, another implantation with, for example, also of Al, is carried out for field protection, or to create a junction termination extension, JTE, as a fourth layer 24 of the semiconductor body. Moreover, the carbon-containing layer 3 is applied all over the top side 20, that is, at the mesa 5 and also at the second layer 22 and the fourth layer 24. The fourth layer 24 may not extend completely across the second layer 22 but may terminate in a lateral direction nearby the mesa 5. Otherwise, for the fourth layer 24 the same may apply as for the first layer 21.

The implanted area is activated at 1700° C., for example, and C is implanted afterwards through the carbon-containing layer 3, see FIG. 8. The carbon-containing layer 3 may be a continuous, hole-free and, thus, uninterrupted layer. For example, the carbon-containing layer 3 is of constant thickness.

In FIG. 8 it is also illustrated that the first layer 21 may optionally be composed of two regions, in FIG. 8 schematically separated from one another by a horizontal line within the first layer 21. In the upper region next to the top side 20, there can be a higher maximum p-doping concentration than in the lower region. Hence, the upper region may be p⁺-doped and may serve as a contact layer, while the lower region can be p-doped. This can apply for all other examples of the semiconductor device 1 as well.

After this, see FIG. 9, a low temperature annealing is performed, for example, at a temperature below 1600° C., in order to diffuse Cᵢ. This will result in a V_{c} poor second layer 22 which is, for example, a drift layer.

After temperature treatment and before application of, for example, electrodes or electrically insulating layers, the carbon-containing layer 3 can completely be removed.

An example of the finished semiconductor device 1 is shown in FIG. 10. The semiconductor device 1 is a Sic-p⁺in diode comprising the mesa 5. In the mesa 5, there can be a fifth layer 25 of the semiconductor body 2 which is, for example, a p⁺ contact layer. Further, the first layer 21 is in the mesa 5. Starting from the first layer 21, the fourth layer 24 can extend laterally next to the mesa 5 so that the JTE is formed. The layers 24, 25 can be regarded as being special parts of the first layer 21, or may be regarded as being separate layers.

Below the mesa 5, there is the second layer 22 which is, for example, slightly n⁻-doped with a concentration of, for example, about 1×10¹⁵ cm⁻³ and may have a thickness of about 70 μm. The third layer 23 is, for example, an n⁺-doped substrate made of SiC and with a doping concentration of about 5×10¹⁸ cm⁻³. A thickness of the third layer 23 is, for example, about 0.25 mm. Lateral sides of the mesa and the exposed regions of the second and fourth layers 22, 24 are coved with an electrically insulating layer 6 which is, for example, of silicon dioxide.

At the fifth layer 25, atop the mesa 5, there is a first electrode 71, like an anode, and at the third layer 23 there is a second electrode 72, like a cathode. As an option, there can be a circumferential sixth layer 26 of the semiconductor body 2 which is, for example, n⁺-doped and which serves as a channel stop. Seen in top view, the mesa 5 can be surrounded all around by the fourth layer 24 and the sixth layer 26, for example, in a rotational symmetric manner.

Otherwise, the same as to FIGS. 1 to 9 may also apply to FIG. 10, and vice versa.

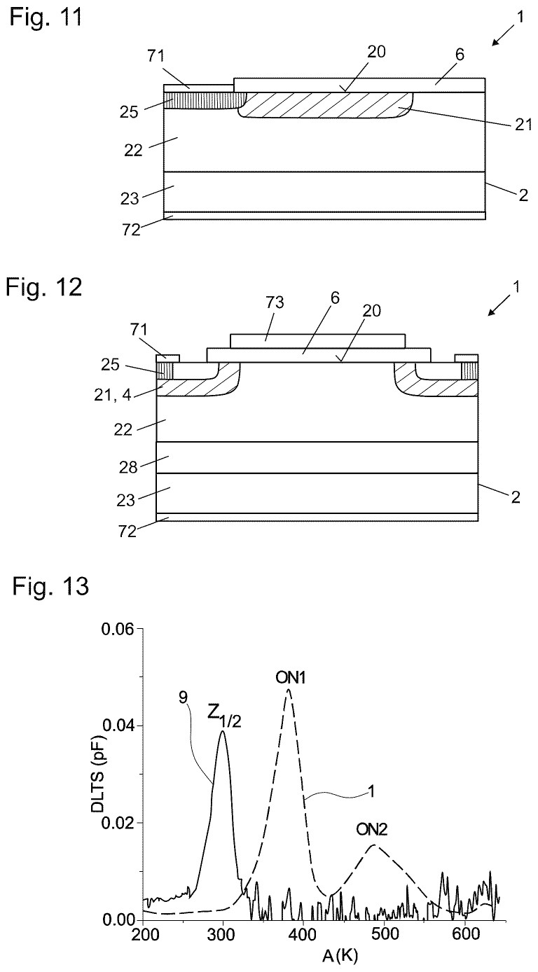

The semiconductor device 1 of FIG. 11 is also a pin diode based on 4H-SiC, but contrary to the semiconductor device 1 of FIG. 10 is of planar fashion so that there is the plane top side 20 without any mesa. In the design of FIG. 11, the first electrode 71 is located at a lateral edge of the device 1. The first layer 21 is of well-shape and is located in the second layer 22. A thickness of the second layer 22 is, for example, about 10 μm. For example, the second layer 22 and the third layer 23 are n-doped with concentrations of about 9×10¹⁵ cm⁻³ and 1×10¹⁹ cm⁻³, respectively.

Otherwise, the same as to FIGS. 1 to 10 may also apply to FIG. 11, and vice versa.

In FIG. 12 it is shown that the semiconductor device 1 is an insulated insulated-gate bipolar transistor, IGBT. Thus, the first layer 21 is a well region. In the well region, there is the fifth layer which is, for example, a p⁺ plug at the first electrode 71 which is, for example, an emitter electrode. Further, in the well region there is a seventh layer of the semiconductor body 2 configured as an emitter region. The second layer 22 is thus an n⁻ drift region. For example, the second layer 22 is a substrate with a thickness between 50 μm and 200 μm. A doping concentration of the drift layer is, for example, about 2×10¹⁴ cm⁻³.

The second layer 22 extends until the top side 20, between two well regions, seen in cross-section. At the top side 20, atop the well regions and said central part of the second layer 22, there is the insulation layer 6 which separates a third electrode 73 from the semiconductor body 2. The third electrode 73 is a gate electrode.

As an option, below the second layer 22 there is an eight layer 28 of the semiconductor body 2 which can be a buffer layer. For example, the buffer layer is n-doped with a maximum doping concentration of about 1×10¹⁸ cm⁻³. A thickness of the buffer layer may be between 2 μm and 10 μm inclusive.

The third layer 23 is located at a side of the second layer 22 remote from the top side 20 or at a side of the eighth layer 28 remote from the top side 20. The third layer 23 is a collector region. The third layer 23 has, for example, a doping concentration of about 1×10¹⁹ cm⁻³. A thickness of the third layer 23 is, for example, between 2 μm and 10 μm inclusive. The second electrode 72 at the third layer 23 is a collector electrode.

Analogously, the semiconductor device 1 can be a metal-insulator-semiconductor field-effect transistor, MISFET, or a metal-oxide-semiconductor field-effect transistor, MOSFET. In this case, the eighth layer 28 may be omitted, and the third layer 23 is an n-doped drain region having, for example, a maximum doping concentration of at least 1×10¹⁸ cm⁻³ or at least 5×10¹⁸ cm⁻³ or at least 1×10¹⁹ cm⁻³ and/or of at most 5×10²⁰ cm⁻³ or at most 2×10²⁰ cm⁻³ or at most 1×10²⁰ cm⁻³. In this case, the seventh layer 27 is a source region and the first and second electrodes 71, 72 are a source electrode and a drain electrode, respectively.

Other than shown, the IGBT or MISFET or MOSFET does not need to be of planar design, but can also be of trench design with the gate electrode 73 accommodated in a trench, not shown.

Otherwise, the same as to FIGS. 1 to 11 may also apply to FIG. 12, and vice versa.

The data in FIG. 13 of a comparative example 9 and of a semiconductor device 1 described herein was obtained by Deep Level Transient Spectroscopy, DLTS. The measurements were done with a reverse bias Vᵣ of −5 V and a pulse voltage Vₚ of 5 V. A filling pulse length was 1 ms at a period width of 0.2 s. The semiconductor device 1 was treated as described in connection with FIGS. 4 to 9 while in case of the comparative example 9 there was not low-dose C ion implantation through a carbon-containing layer. It can be seen that in the comparative example 9 there is a strong presence of V_{c} as indicated by the Z_{1/2} peak. Contrary to that, in the exemplary semiconductor device 1 there is no Z_{1/2} peak, but instead peaks associated with the states ON1, ON2 appear.

Typically, the V_{c} concentration in as grown n-type 4H-SiC is between 10¹¹ cm⁻³ and 10¹² cm⁻³. With such concentrations, the minority carrier lifetime is around 1 μs. This value is rather low and not suitable for SiC bipolar devices. An acceptable [V_{c}] is, for example, lower than 10¹¹ cm⁻³. Since High Voltage SiC bipolar devices rely on regions with low doping concentration, that is, for example, 10¹⁴ cm⁻³, the threshold for detection of [V_{c}] may be around 10¹⁰ cm⁻³. Hence, that the threshold limit for V_{c} detection is about four orders of magnitude lower than the doping concentration. Thus, a SiC bipolar device with a doping concentration of 10¹⁴ cm⁻³ and a [V_{c}] of 5×10¹⁰ cm⁻³ to 8×10¹⁰ cm⁻³ or even lower would work fine.

The method described herein goes ahead with the following benefits, for example:
Performing C implantation in the anode through the C-cap allows effective V_{c} removal, because Cᵢ are supplied by the C-cap and by the implanted C.
Unlike in Hamada et al., C implantation can be done at low doses, thus avoiding amorphization in the drift layer.
Also unlike in Hamada et al., C implantation is done in the anode and not in the drift layer, thus avoiding doping compensation, because Cᵢ are acceptors in n-type Sic.
Unlike in Storasta et al., no structuring, like etching, of the C-containing layer is needed.
Unlike in Ayedh et al., no residual V_{c} are left, because Cᵢ are provided not only by the C-cap but also from the implantation step.
The C low dose implantation avoids excessive formation of defects in the anode layer, that is, the first layer, thus preserving the injection efficiency.
7) Reverse engineering is possible in the final product, for example, by secondary-ion mass spectrometry, SIMS, in order to detect C in the anode layer.
Reverse engineering is possible in the final product also, for example, by DLTS, in order to detect ON1 and ON2 states.
Anode layers of any thickness are possible to be formed.

The components shown in the figures follow, unless indicated otherwise, exemplarily in the specified sequence directly one on top of the other. Components which are not in contact in the figures are exemplarily spaced apart from one another. If lines are drawn parallel to one another, the corresponding surfaces may be oriented in parallel with one another. Likewise, unless indicated otherwise, the positions of the drawn components relative to one another are correctly reproduced in the figures.

The invention described here is not restricted by the description on the basis of the exemplary embodiments. Rather, the invention encompasses any new feature and also any combination of features, which includes in particular any combination of features in the patent claims, even if this feature or this combination itself is not explicitly specified in the patent claims or exemplary embodiments.

### LIST OF REFERENCE SIGNS

1 semiconductor device
2 semiconductor body
20 top side of the semiconductor body
21 first layer of the semiconductor body
22 second layer of the semiconductor body
23 third layer of the semiconductor body
24 fourth layer of the semiconductor body
25 fifth layer of the semiconductor body
26 sixth layer of the semiconductor body
27 seventh layer of the semiconductor body
28 eighth layer of the semiconductor body
3 carbon-containing layer
4 dopant
5 mesa
6 insulation layer
71 first electrode
72 second electrode
9 comparative example
A absolute temperature in K
Al aluminum ion implantation
C concentration in cm⁻³
C carbon ion implantation
DLTS deep level transient spectroscopy data in pF
ON1 first other level in the band structure
ON2 second other level in the band structure
S . . . method step
T depth from the top side into the semiconductor body
Z_{1/2} active level in the bandgap

1. A method for producing a semiconductor device comprising the following steps in the stated order:
A) providing a semiconductor body having a top side, the semiconductor body is based on SiC,
B) producing a first layer of the semiconductor body next to the top side by doping with a dopant,
C) applying a carbon-containing layer on the top side,
D) implanting C into the first layer through the carbon-containing layer with a dose of at most 1×10¹² cm⁻², and
E) performing a temperature treatment of the semiconductor body when the carbon-containing layer is still present on the top side,
wherein a concentration of the dopant provided in step B) and being activated is at least three times and at most thirty times a concentration of C implanted in step D).

2. The method according to claim 1, wherein the concentration of the dopant provided in step B) and being activated is at least six times and at most fifteen times the concentration of C implanted in step D).

3. The method according to claim 1,
wherein in step E) the temperature treatment includes applying a first temperature,
wherein the first temperature is between 1400° C. and 1800° C. inclusive,
wherein in step E) C diffuses from the carbon-containing layer into the first layer.

4. The method according to claim 1, further comprising a step B2) between steps B) and D):
B2) activating the dopant by applying a second temperature,
wherein the second temperature is between 1400° C. and 1800° C. inclusive.

5. The method according to claim 1,
wherein in step E) C diffuses from the carbon-containing layer into the first layer and the dopant is activated,
wherein in step E) the temperature treatment includes applying a third temperature,
wherein the third temperature is between 1400° C. and 1800° C. inclusive, and
wherein between steps A) and E) a temperature of the semiconductor body is kept below 800° C.

6. The method according to claim 1,
wherein in step B) the doping is provided by means of ion implantation.

7. The method according to claim 1,
wherein the dopant is Al,
wherein the dopant is provided with a dose between 10¹³ cm⁻² and 10¹⁶ cm⁻².

8. The method according to claim 1,
wherein in step D) a first implantation energy is at least 10 keV and is at most 300 keV.

9. The method according to claim 1,
wherein after step D) a first box profile depth of the dopant is larger than a second box profile depth of C,
wherein the first box profile depth is between 0.1 μm and 1.2 μm inclusive.

10. The method according to claim 1,
further comprising a step B1) between steps B) and C):
B1) etching the semiconductor body so that a mesa is formed, an etching depth is larger than a thickness of the first layer.

11. The method according to claim 1,
wherein in step C) the carbon-containing layer is applied all over the semiconductor body,
wherein the carbon-containing layer comprises at least one of graphite and a photoresist, and a thickness of the carbon-containing layer is at least 0.1 μm and at most 0.9 μm.

12. The method according to claim 1,
wherein in the finished semiconductor device the semiconductor body further comprises a second layer directly on a side of the first layer remote from the top side,
wherein the second layer is doped with a lower doping concentration than the first layer,
wherein a thickness of the second layer is between 10 μm and 100 μm.

13. The method according to claim 1,
wherein the first layer is of 4H-SiC, and
wherein in the finished semiconductor device the first layer is an anode layer.

14. The method according claim 1,
wherein the finished semiconductor device is a pin diode or is an insulated-gate bipolar transistor, IGBT, or a reverse-conducting insulated-gate bipolar transistor, RC-IGBT.

15. (canceled)
